(19) United States
(12) Patent Application Publication
(10) Pub. No.: US 2008/0203852 A1
(43) Pub. Date: Aug. 28, 2008

(54) Circuit and Method For Analog-Driving a Capacitive Load, in Particular a Piezoelectric Actuator

(76) Inventors: Bernhard Gottlieb, Munchen (DE); Andreas Kappel, Brunnthal (DE); Tim Schwebel, Munchen (DE); Carsten Wallenhauer, Schwarzheide (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 12/065,708

(22) PCT Filed: Sep. 4, 2006
(86) PCT No.: PCT/EP06/65972

§ 371 Date: Mar. 4, 2008

(30) Foreign Application Priority Data
Sep. 5, 2005 (DE) 10 2005 042 108.3

(51) Int. Cl. H01L 41/00; H03K 3/00

(52) U.S. Cl. 310/317; 327/111

(57) ABSTRACT

A circuit for analogously controlling a capacitive charge, has a drive source used to provide an operating voltage or an operating flow used to charge the capacitive charge, a circuit arrangement used to charge and discharge the charge, and a storage capacity used to intermediately store the charge of the charge during the discharge of the charge and to emit intermediately stored charge to the charge during charging of the charge. In a method for analogously controlling a capacitive charge by applying a operational voltage or an operating flow of a drive source in order to charge the capacitive charge onto the charge and to discharge the charge, during a first discharge phase, the charge of the charge is intermediately stored in a storage capacity and during a first charging phase, which is used to charge the charge, the charge from the charge capacity is charged in the charge.

Circuit and method for analog-driving a capacitive load, in particular a piezoelectric actuator

The invention relates respectively to a circuit for analog-driving a capacitive load according to the features in the preamble of claim 1 and to a method for analog-driving a capacitive load according to the features in the preamble of claim 9.

Piezoelectric actuators are employed multifariously as controlling elements. Different requirements are in all manner of applications placed on parameters such as efficiency and signal quality etc. The actuators are able to achieve the required functionality at low electronic-component costs only by means of electronic components matched to the specific applications. The innovation herein described is aimed at applications in which medium to high efficiency is demanded of the components along with very high signal quality and modest requirements in terms of, for instance, switching times, tolerances, and power dissipation. An exemplary application is a driver stage of a piezo ring motor described in EP 1 098 429 B1. A piezo ring motor of said type includes as a solid-body-actuator drive device a drive body having a cylindrical drive surface, with said surface being able to be embodied also by the inside of an annular drive body, at least two solid-body actuators that cause the drive ring to oscillate in a drive plane, a drive shaft resting on the drive surface perpendicularly to the drive plane and caused to rotate by said oscillating, and a switching device for driving the solid-body actuators. Particularly in applications of said drive that are near to users it is required for the cited parameters to be combined to insure a low noise level, efficiency, and low costs.

Piezoelectric driver concepts are based on switched-mode power-supply output stages, analog output stages, charge pumps, or combinations of the cited principles. Although clocked output stages such as switched-mode power-supply and hybrid output stages offer a high level of efficiency, they have a poor signal quality owing to quantizing of the output signal and give rise to various EMC problems (EMC: electromagnetic compatibility) due to steep transients. Although the signal quality can be significantly improved through measures such as increasing the switching frequency and signal filtering, that will increase both circuitry expenditure and the demands placed on the components. Higher electronic-component costs will accordingly also ensue under the cited boundary conditions.

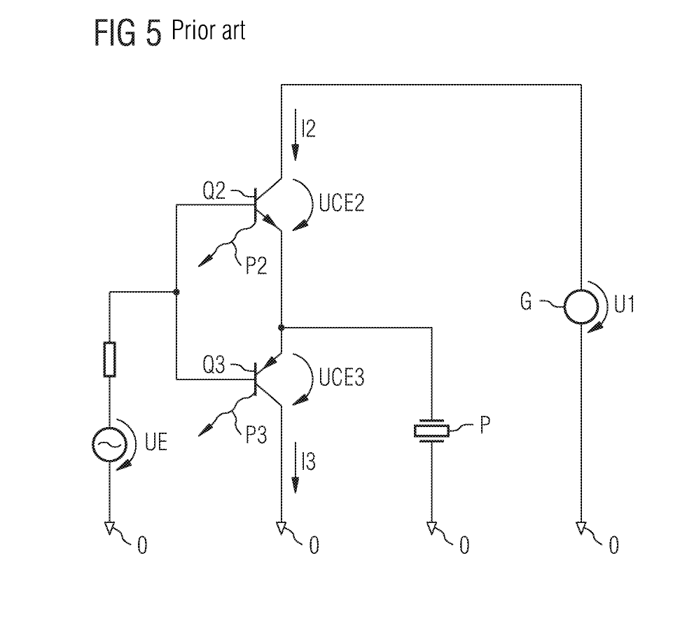

A known push-pull output stage consists inter alia of a pair of complementary emitter followers of a second and third transistor Q2, Q3, as shown in FIG. 5. A capacitive load P is therein connected between, on the one hand, the collector-emitter paths of the second and third transistor Q2, Q3 and, on the other, a common reference potential 0. An output stage of said type constitutes a current amplifier that simulates a voltage-time function being applied to the input on the load P with low impedance. Said structure's efficiency is low because owing to a voltage drop UCE2, UCE3 over the collector-emitter path of the two transistors Q2, Q3 and a current flow 12, 13, due to the load P, over a time interval T a power having the magnitude P2 or, as the case may be, P3 is converted at the respective transistor Q2, Q3 into heat in keeping with

P2(T)=(U1−UE)·12(T)=UCE2·12(T) where UBE2≈0V and

P3(T)=(UE−0V)·13(T)=UCE3·13(T) where UBE3−≈0V,

with base-emitter voltages UBE2, UBE3 of the two transistors Q2, Q3 being virtually zero.

However, the circuit's functioning requires only a small difference in potential, dependent on transistor type, or, as the case may be, voltage drop UCE2, UCE3 of the collector-emitter paths.

The object of the invention is to improve a circuit or, as the case may be, method for analog-driving a capacitive load. The aim is to advantageously reduce the voltage or, as the case may be, the respective voltage drop UCE of the collector-emitter paths to a value necessary for the transistors' proper functioning. A circuit of said type should in particular be able to be operated with low power consumption and preferably improved efficiency.

Said object is achieved by means of a circuit for analog-driving a capacitive load having the features of claim 1 or, as the case may be, a method for analog-driving a capacitive load having the features of claim 9. Independently advantageous is an implementation in a solid-body-actuator drive device having the features of claim 8. Advantageous embodiments are the subject matter of dependent claims.

What is accordingly preferred is a circuit for analog-driving a capacitive load having a drive source for providing an operating voltage or an operating current for charging the capacitive load, having a circuit arrangement for charging and discharging the load, and having a storage capacitor for buffering charge from the load while the load is being discharged and for releasing buffered charge to the load while the load is being charged.

What is advantageous is a circuit having a further circuit arrangement for switching the load during a first discharging phase for discharging the load into the storage capacitor, for switching the load to a reference potential during a second discharging phase for discharging the load, for switching the load during a first charging phase for charging the load from the storage capacitor, and for switching the load during a second charging phase for charging the load from the drive source.

What is advantageous is a circuit in the case of which the reference potential is a common reference potential also of the drive source and storage capacitor.

What is advantageous is a circuit in the case of which the further circuit arrangement has switches which for switching charging and discharging of the load are driven by a subsidiary circuit or control means. What is advantageous is a circuit in the case of which the circuit arrangement and further circuit arrangement have as switches transistors for switching charging and discharging of the load or, as the case may be, storage capacitor. What is advantageous is a circuit in the case of which the circuit arrangement and further circuit arrangement has diodes and/or Zener diodes that are connected between, on the one hand, the storage capacitor and, on the other, the subsidiary control means for driving the switches or transistors for switching the first and second charging phase and for switching the first and second discharging phase.

What is advantageous is a circuit in the case of which the load is embodied by means of at least one piezoelectric actuator.

Independently preferred is a solid-body-actuator drive device having a drive body having a cylindrical drive surface, having at least two solid-body actuators that cause the drive body to oscillate in a drive plane, having a drive shaft resting on the drive-body surface and caused to rotate by said oscillating, and having a circuit for driving the solid-body actuators, with the solid-body actuators each being embodied by means of a capacitive load and the circuit being embodied having a storage capacitor of said type.

Inventively preferred is a method for analog-driving a capacitive load by applying an operating voltage or operating current of a drive source for charging the capacitive load to the load and for discharging the load, with charge of the load being buffered into a storage capacitor during a first discharging phase and, during a first charging phase, charge being charged from the storage capacitor into the load for charging the load. What is advantageous is a method in the case of which a solid-body actuator, in particular a piezoelectric solid-body actuator, is driven as the capacitive load by charging and discharging.

The preferred structure of the circuit forms a purely analog, value- and time-continuous output stage for driving capacitive loads. The structure is based on a push-pull output stage consisting of a complementary emitter follower. The circuit is modified in such a way that a part of the energy stored in the load is in a simple manner reclaimed for powering the structure.

What is disadvantageous about a circuit of said type compared with switched-mode power-supply output stages is basically poorer efficiency. A multiplicity of advantages predominate, though, for numerous applications.

What is advantageous is, for example, a simple structure. Of particular advantage is a nonetheless very good signal quality due to the capacitive load's not being driven under clocked control. Also advantageous is an even distributing of thermal loading among a plurality of transistors. A thus constituted output stage can furthermore scarcely be a source of EMC disruptions as it is not operated under clocked control. What can be achieved is medium to high efficiency thanks to energy reclamation. What is advantageous is a very economical structure thanks to the use of standard components, to needing no inductive resistors, and to the lack of stringent tolerance requirements.

An exemplary embodiment is explained in more detail below with the aid of the drawing:

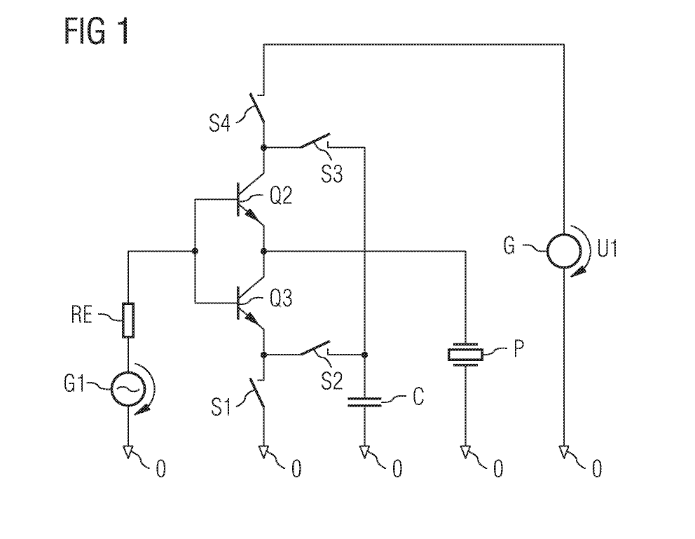

FIG. 1 shows a circuit according to a first embodiment variant having a storage capacitor,

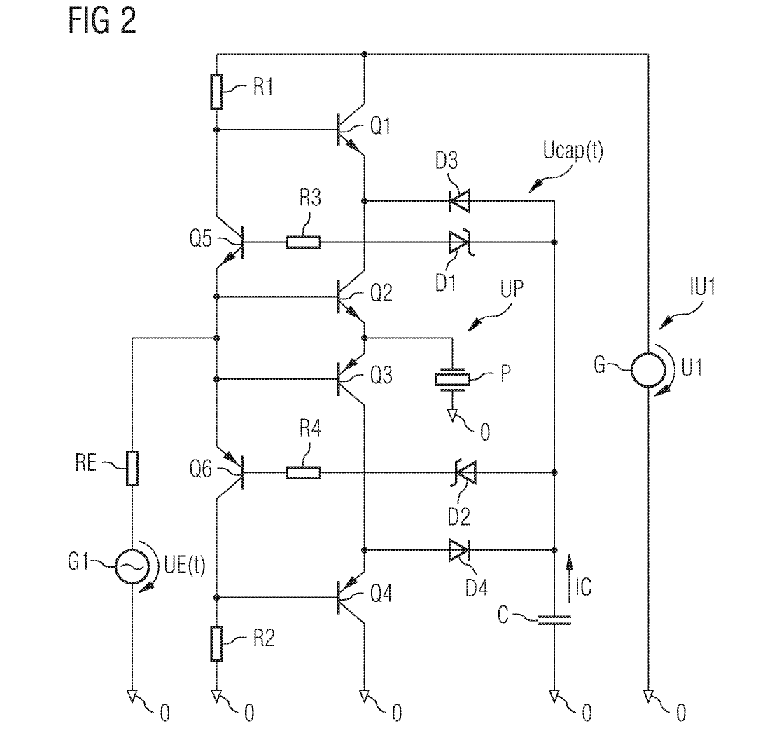

FIG. 2 shows a circuit according to a second embodiment variant having a storage capacitor,

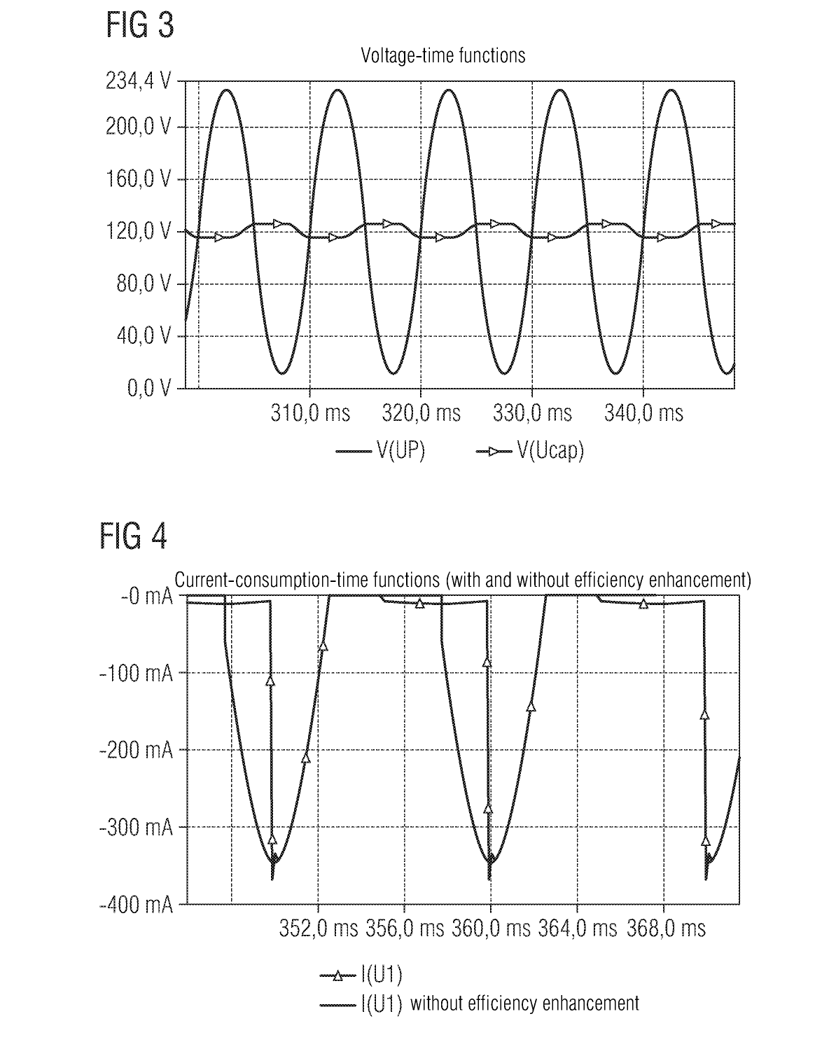

FIG. 3 shows voltage-time functions of a preferred circuit of such type contrasted with a circuit not having a storage capacitor,

FIG. 4 shows current-consumption-time functions of a preferred circuit of such type contrasted with a circuit not having a storage capacitor, and

FIG. 5 shows a circuit according to the prior art not having a storage capacitor of such kind.

The embodiment variants as per FIG. 1 and FIG. 2 constitute a time- and value-continuous output stage for driving capacitive loads P with a high level of efficiency, high signal quality, and low-level component requirements. The structure is characterized by a storage capacitor C linked via switches S1-S4 generally and, specifically, diodes D1-D4 or transistors Q1, Q3-Q6 to the collectors of two complementary output-stage transistors Q2, Q3. The storage capacitor C absorbs energy while the capacitive load P is being discharged and releases it again to said load partially for charging it. A part of the charge or, as the case may be, energy stored in the capacitive load P is in that way reclaimed.

FIG. 1 shows an exemplary circuit for analog-driving a capacitive load P, which circuit is embodied preferably by means of a capacitive solid-body actuator, in particular a piezoelectric actuator.

A drive source G for providing an operating voltage U1 or operating current for charging the load P is by means of a first terminal connected as is the load P to a reference potential 0.

A circuit arrangement for charging and discharging the load P includes in a manner known per se a second and third transistor Q2, Q3. The second and third transistor Q2, Q3 are via their series-connected collector-emitter paths connected between a second terminal of the drive source G and the reference potential 0. The base terminals of the second and third transistor Q2, Q3 are, for being driven, connected via a base-terminal resistor to a suitable control circuit in the form of, for instance, a control-terminal drive source G1. Depending on the momentary switching state, the control-terminal drive source G1 makes a control-terminal operating voltage available as a drive signal UE(t) with respect to the reference potential 0.

The capacitive load P is by means of one of its terminals connected between the two collector-emitter paths of the second and third transistor Q2, Q3. The load P is by means of its other terminal applied to the reference potential 0. Depending on the potential value at the base terminals of the second and third transistor Q2, Q3, the capacitive load P is thereby charged via the operating voltage U1 of the drive source G and via the second transistor Q2 or discharged via the third transistor Q3 towards the reference potential 0.

The circuit includes as an essential element a storage capacitor C, for example an electrolytic capacitor, for buffering charge from the load P while the load P is being discharged and for releasing thus buffered charge to the load P while the load P is being charged.

The storage capacitor C is connected by means of four switches, which is to say a first to a fourth switch S1-S4 as a further circuit arrangement, to the circuit arrangement consisting of the second and third transistor Q2, Q3. The first switch S1 is connected between the reference potential 0 and third transistor Q3. The second switch S2 is connected between, on the one hand, the first switch S1 and third transistor Q3 and, on the other, the first terminal of the storage capacitor C. The second terminal of the storage capacitor C is applied to the reference potential 0. The fourth switch S4 is connected between, on the one hand, a node between the third switch S3 and the collector of the second transistor Q2 and, on the other, the drive source G. The first terminal of the storage capacitor C is furthermore applied to the third switch S3 embodying a switchable connection to the node between the fourth switch S4 and the collector of the second transistor Q2. The switches S1-S4 are for switching charging and discharging of the load P preferably driven by a circuit or control device that is subsidiary to the circuit shown and which also controls the potential that for switching is applied to the two base terminals of the second and third transistor Q2, Q3.

The potential of the storage capacitor C adjusts to a value between the reference potential 0 and the operating voltage U1. The current flow is controlled by the switches S1-S4 in such a way that for charging a capacitive actuator as the load P the storage capacitor C will continue being charged by the load P via the second switch S2 as long as an actuator potential or, as the case may be, load potential of the load P exceeds a potential of the storage capacitor C. The load P will be discharged directly towards the reference potential 0 via the first switch S1 as soon as the load potential becomes too small with respect to the potential of the storage capacitor C. That means the corresponding transistor Q2, Q3 will continue being supplied with current IC from the storage capacitor C as long as a difference in potential Ucap(t) (see FIG. 2) above the storage capacitor C insures sufficient voltage UCE for the circuit's functioning.

The load P is charged complementarily. The load P will as long as the actuator potential or, as the case may be, load potential of the load P is less than the potential of the storage capacitor C continue being charged via the third switch S3 using the energy or, as the case may be, charge buffered in the storage capacitor C. The load P will be charged with the operating voltage U1 via the fourth switch S4 directly from the drive source G as soon as the load potential exceeds the potential of the storage capacitor C.

FIG. 2 shows an embodiment variant that has been modified compared with FIG. 1 and in the case of which an automatic electronic circuit is provided instead of the switchable switches S1-S4. The load P continues actually being charged or discharged via the application of a corresponding control-terminal potential to the base terminals of a second and third transistor Q2, Q3, as in the case of the embodiment variant as per FIG. 1. Charging and discharging of the storage capacitor C is, conversely, switched via appropriately connected further transistors Q1, Q3-Q6 and diodes D1-D4.

The second and third transistor Q2, Q3 are by means of their base terminals in turn connected via a base-terminal resistor RE to a control-terminal drive source G1 which builds up a control potential as the drive signal UE(t) with respect to a reference potential 0. A capacitive load P in the form preferably of a piezoelectric actuator is in turn connected between, on the one hand, the reference potential 0 and, on the other, the two collector-emitter paths of the second and third transistor Q2, Q3. A drive source G for providing an operating voltage U1 or operating current for charging the capacitive load P is connected between the reference potential 0 and a collector-emitter path of a first transistor Q1. The second terminal of the collector-emitter path of the first transistor Q1 forms the input of the collector-emitter path of the second transistor Q2. A base terminal of the first transistor Q1 is connected via a first resistor R1 to the terminal, being applied to the first transistor Q1, of the drive source G. The base terminal of the first transistor Q1 is furthermore connected to a collector-emitter path of a fifth transistor Q5 whose second terminal of its collector-emitter path is connected to the base terminals of the second and third transistor Q2, Q3. The base terminals of the second and third transistor Q2, Q3 are furthermore connected via a collector-emitter path of a sixth transistor Q6 and via a downstream second resistor R2 to the reference potential 0. A fourth transistor Q4 is connected by means of its collector-emitter path between the reference potential 0 and the collector-emitter path of the third transistor Q3 to its terminal facing away from the second transistor Q2.

The storage capacitor C is charged via a fourth diode D4 connected between, on the one hand, a node between the third and fourth transistor Q3, Q4 and, on the other, the first terminal of the storage capacitor C. The storage capacitor C is charged accordingly in a first discharging phase when the capacitive load P is discharged via the third transistor Q3. The storage capacitor C is discharged in a first charging phase via a third diode D3 connected between the first terminal of the storage capacitor C and a node between the first and second transistor Q1, Q2. Discharging of the charge of the storage capacitor C will, with the second transistor Q2 and third transistor Q3 switched appropriately, thereby result in charging of the capacitive load P.

For discharging the capacitive load P in a second discharging phase the third and fourth transistor Q3, Q4 are switched to conduct towards the reference potential 0. Inter alia a second diode D2 embodied as a Z or, as the case may be, Zener diode and connected between the storage capacitor C and a fourth resistor R4 serves for that purpose, with the fourth resistor R4 being applied by means of its further terminal to the base terminal of the sixth transistor Q6. Changing of the capacitive load P during a second charging phase from the drive source G via the first and second transistor Q1, Q2 that are switched appropriately to conduct is enabled by means of corresponding driving, for which purpose a first diode D1, in particular a Z diode, is connected between a third resistor R3 and the first terminal of the storage capacitor C. The further terminal of the third resistor R3 is applied to the base terminal of the fifth transistor Q5.

The first switch S, as well as a suitable drive circuit for the first switch S1 as per FIG. 1 has according to FIG. 2 been replaced with a structure consisting of the sixth and fourth transistor Q6 and Q4, the fourth and second resistor R4 and R2, and a second Z diode D2. The difference in potential between the storage capacitor C and load potential of the load P is measured via the circuit path consisting of the second Z diode D2 and the sixth transistor Q6. The load potential and drive signal UE(t), which changes over time, for the base terminals of the second and third transistor Q2, Q3 are approximately the same in magnitude. The sixth transistor Q6 will remain active, meaning switched to conduct, as long as the difference in potential exceeds the sum of the Zener voltage of the second diode D2 and the voltage drop of the base-emitter path of the sixth transistor Q6. The base potential of the fourth transistor Q4 is thereby set to the load potential. The fourth transistor Q4 is thereby deactivated or, as the case may be, becomes insulating. Said condition corresponds to an open switch S1 as per FIG. 1. If the difference in voltage between the potential of the storage capacitor C and the load potential reduces below the sum of the Zener voltage of the second diode D2 and the voltage drop over the base-emitter path of the sixth transistor Q6, then the sixth transistor Q6 will be deactivated and the fourth transistor Q4 activated or, as the case may be, will conduct via the base resistor in the form of the second resistor R2. Said condition corresponds to closed switch S as per FIG. 1.

The equivalent circuit for the fourth switch S4 is implemented complementarily to the equivalent circuit for the first switch S as per FIG. 1 and consists of the first and fifth transistor Q1, Q5, the third and first resistor R3, R1, and the first diode D1.

An exemplary simulation whose signal curves are shown in FIG. 3 and FIG. 4 was performed for the circuit as per FIG. 2. The drive signal UE(t) is therein a sine function having a direct-current component U=120V. The voltage Ucap(t) corresponds to the difference in potential above the storage capacitor C. The charging and discharging cycle of the storage capacitor C as a function of the drive signal UE(t) can clearly be seen in FIG. 3. The direct-current component of the function or, as the case may be, voltage Ucap(t) is the same as the direct-current component of the drive signal UE(t). Shown in FIG. 4 is the current consumption from the drive source G above its power supply U1. Corresponding curves of an inventive structure are therein contrasted with a known output stage as per FIG. 5. The graph clearly shows that half the power of the load P is made available from the storage capacitor C.

That means the power draw can by means of the preferred structure be halved compared with known analog concepts without the signal quality's being adversely affected thereby.

Merely exemplary simulation parameters of a circuit as per FIG. 2 for achieving values as per FIGS. 3 and 4 are a load-capacitance value of 5 μF, a storage-capacitance value of 47 μF, resistance values of the first and second resistor R1, R2 of 22 kΩ, resistance values of the third and fourth resistor R3, R4 of 82 kΩ, a resistance value of the base terminal resistor RE of 47Ω, an operating voltage U1=250V, and a control-terminal operating voltage as the drive signal UE(t)=120V+110V·sin(t 2π 100 Hz).

What is claimed is:

1. A circuit for analog-driving a capacitive load comprising:
a drive source for providing an operating voltage or operating current for charging the capacitive load,
a circuit arrangement for charging and discharging the load,
and
a storage capacitor for buffering charge from the load while the load is being discharged and for releasing buffered charge to the load while the load is being charged.

2. The circuit according to claim 1, comprising a further circuit arrangement
for switching the load during a first discharging phase for discharging the load into the storage capacitor,
for switching the load to a reference potential during a second discharging phase for discharging the load,
for switching the load during a first charging phase for charging the load from the storage capacitor, and
for switching the load during a second charging phase for charging the load from the drive source.

3. The circuit according to claim 2, wherein the reference potential is a common reference potential also for the drive source and storage capacitor.

4. The circuit according to claim 2, wherein the further circuit arrangement comprises switches which for switching charging and discharging of the load are driven by a subsidiary circuit or control means.

5. The circuit according to claims 2, wherein the circuit arrangement and further circuit arrangement comprise as switches transistors for switching charging and discharging of the load or, as the case may be, storage capacitor.

6. The circuit according to claim 4, wherein the circuit arrangement and further circuit arrangement comprise diodes and/or Zener diodes that are connected between, on the one hand, the storage capacitor and, on the other, the subsidiary control means for driving the switches or transistors for switching the first and second charging phase and for switching the first and second discharging phase.

7. The circuit 2 according to claim 1, wherein the load is embodied by means of a at least one piezoelectric actuator.

8. A solid-body-actuator drive device, comprising
a drive body having a cylindrical drive surface,
at least two solid-body actuators causing the drive body to oscillate in a drive plane,
a drive shaft resting on the drive-body surface and caused to rotate by said oscillating,
a circuit for driving the solid-body actuators,
the solid-body actuators are each embodied by means of a capacitive load and the circuit comprising a drive source for providing an operating voltage or operating current for charging the capacitive load, a circuit arrangement for charging and discharging the load, and a storage capacitor for buffering change from the load while the load is being discharged and for releasing buffered charge to the load while the load is being charged.

9. A method for analog-driving a capacitive load, comprising the steps of:
applying an operating voltage or operating current of a drive source for charging the capacitive load to the load, and
discharging the load,
buffering a charge of the load into a storage capacitor during a first discharging phase and, during a first charging phase for charging the load, charging a charge from the storage capacitor into the load.

10. The method according to claim 9, wherein a solid-body actuator is driven as the capacitive load by charging and discharging.

11. The method according to claim 9, wherein a piezoelectric solid-body actuator is driven as the capacitive load by charging and discharging.

12. A method for operating a solid-body-actuator drive device comprising a drive body having a cylindrical drive surface, at least two solid-body actuators causing the drive body to oscillate in a drive plane, a drive shaft resting on the drive-body surface and caused to rotate by said oscillating, a circuit for driving the solid-body actuators, and the solid-body actuators are each embodied by means of a capacitive load, wherein the circuit comprises a drive source, a circuit arrangement for charging and discharging the load, and a storage capacitor, the method comprising the steps of:
applying an operating voltage or operating current of the drive source for charging the capacitive load to the load, and
discharging the load,
buffering a charge of the load into the storage capacitor during a first discharging phase and, during a first charging phase for charging the load, charging a charge from the storage capacitor into the load.

13. The method according to claim 12, wherein a solid-body actuator is driven as the capacitive load by charging and discharging.

14. The method according to claim 12, wherein a piezoelectric solid-body actuator is driven as the capacitive load by charging and discharging.
